(19) United States
(12) Patent Application Publication
(10) Pub. No.: US 2010/0118496 A1
(43) Pub. Date: May 13, 2010

(54) HEAT SINK FOR MODULAR LED FLOOD LIGHT

(76) Inventor: Chi Wai Lo, Tsuen Wan (HK)

Correspondence Address: ITALIA IP, 3500 WEST OLIVE AVE., SUITE 300, BURBANK, CA, 91505, US

(21) Appl. No.: 12/420,332

(22) Filed: Apr. 8, 2009

(30) Foreign Application Priority Data
Nov. 11, 2008 (CN) 200820203227.6

(51) Int. Cl. H05K 7/20

(52) U.S. Cl. 361/710

(57) ABSTRACT

A heat sink which is adaptable to form a module of a modular luminaire which uses LED light sources. The heat sink may have cooling fins projecting in three directions from a base member and two walls projecting from the base member. Fastener holes are provided as channels extending the length of the heat sink at the base of cooling fins, for example. This configuration enables a novel heat sink having both cooling fins and also structure corresponding to screw holes to be formed by extrusion. One channel may be centered within the heat sink, so that the heat sink can be connected by two opposed fasteners and rotated thereabout to enable minor angular positional adjustment within an associated luminaire.

### CROSS-REFERENCE TO RELATED APPLICATIONS

This application claims the benefit of the filing date under 35 USC 119(a) of Chinese Patent Application No. 200820203227.6, filed Nov. 11, 2008, the contents of which are incorporated herein by reference. This application is also related to Patent Applications entitled MODULAR LED FLOOD LIGHT and LENS FOR LIGHT EMITTING DIODES MOUNTED ON A HEAT SINK, both of common ownership with the present invention, and both filed of even date herewith.

### FIELD OF THE INVENTION

The present invention relates to illumination, and more particularly to a heat sink which is intended to support a plurality of light emitting diodes.

### BACKGROUND OF THE INVENTION

Lights for illuminating large areas such as roads, parking lots, fields, and the like have long been provided. Lighting technology for such lights has progressed from incandescent to specialized high powered types such as sodium vapor and mercury vapor. However, it has become desirable to utilize more efficient light sources, as efficiency relates to units of light output per unit of electrical input.

Light emitting diodes (hereinafter LEDs) are among the most efficient types of light sources commercially available today. LEDs enjoy not only relatively high efficiency, but offer long life and relatively uncomplicated construction. LEDs have progressed to the point where white light producing LEDs could be employed in many applications.

Heat sinks for luminaires using LEDs have typically suffered from the characteristic that they are not configured so that they may be extruded or cut to any desired length without sacrificing certain structural features. Notably, structure formed in the end of an extrusion may be lost when the extrusion is cut or is extruded without forming end structures. An example of end structures which may be necessary is tapped holes for receiving fasteners. It would not be feasible to produce an extrusion having a tapped or threaded hole extending the full length of the extrusion.

This leads to the situation that many different models must be designed, produced, and stocked, and replacement parts be made available for each model. While this situation offers great versatility in providing varieties of luminaires, such convenience comes at economic cost.

A need exists for mass producing heat sinks for luminaires using white LEDs in many light output capacities, so that individual luminaires employing LEDs may be produced in different capacities and configurations using a limited number of different models or designs of heat sinks. As a consequence, it becomes desirable to provide a heat sink for supporting and dissipating heat from LEDs which lends itself to modular construction and efficient fabrication.

### SUMMARY OF THE INVENTION

The present invention addresses the above stated need by providing a design for a heat sink which is usable with modular luminaires which utilize LEDs. Firstly, the novel heat sink can be fabricated by extruding a material such as aluminum or its alloys. Secondly, the novel heat sink can be extruded to any desired length and cut to any length while preserving all of its features, especially those of holes for receiving fasteners.

The present invention addresses the issue of providing holes for fasteners inserted from the end, or alternatively stated, for fasteners which must be installed into longitudinally oriented fastener holes. This is accomplished by forming generally circular channels at certain points within the heat sink body. By using a relatively soft metal such as aluminum or its alloys, fasteners such as self-tapping screws or simply screws formed from strong materials such as certain steels will be immediately compatible with the extruded heat sink.

In another aspect, the heat sink has a centrally located hole, which enables the heat sink to be rotated about its central axis on two fasteners. This enables the heat sink to be angularly adjusted prior to fastening. Such adjustment is possible with certain luminaires such as that which is the subject of one of the above referenced copending applications.

The novel heat sink accommodates a narrow elongated array of LEDs, such as a straight row. This enables width of the light generated source to be varied by selecting the number of heat sinks which are to be installed next to one another.

In summary, the novel heat sink accommodates variations in both length and width of an array of LEDs in a luminaire. It also enables minor angular adjustment for purposes of modifying projection patterns of light.

It is therefore an object of the invention to provide a design for a heat sink which is modular and highly versatile in supporting dimensions and configurations of LED arrays for luminaires.

It is an object of the invention to provide improved elements and arrangements thereof by apparatus for the purposes described which is inexpensive, dependable, and fully effective in accomplishing its intended purposes.

These and other objects of the present invention will become readily apparent upon further review of the following specification and drawings.

### BRIEF DESCRIPTION OF THE DRAWINGS

Various objects, features, and attendant advantages of the present invention will become more fully appreciated as the same becomes better understood when considered in conjunction with the accompanying drawings, in which like reference characters designate the same or similar parts throughout the several views, and wherein:

FIG. 1 is a top perspective view of a modular luminaire according to at least one aspect of the invention.

FIG. 2 is an exploded top perspective view of FIG. 1.

FIG. 3 is an exploded top perspective detail view of components seen at the center of FIG. 1.

FIG. 4 is a top perspective detail view of the lowermost component of FIG. 3.

FIG. 5 is an end detail view of FIG. 4, drawn to enlarged scale.

FIG. 6 is a diagrammatic representation of possible positions and adjustments to the direction of projection of light from LEDs, according to a further aspect of the invention.

### DETAILED DESCRIPTION

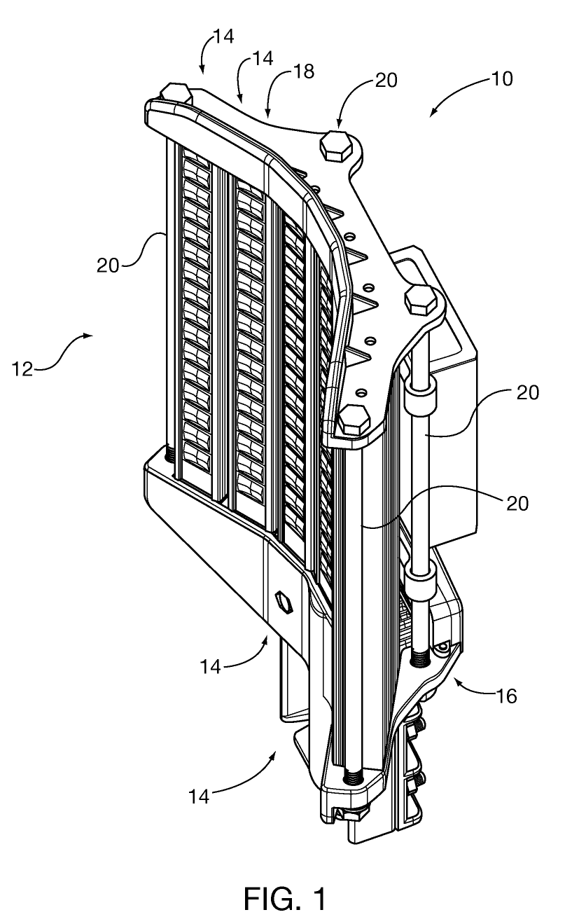

FIG. 1 of the drawings shows a modular luminaire 10 which uses LEDs 12 (not all of which are individually called out by reference numeral), which may utilize a heat sink 14 according to at least one aspect of the invention. Plural heat sinks 14 are utilized in the modular luminaire 10 for supporting and dissipating heat from the LEDs 12.

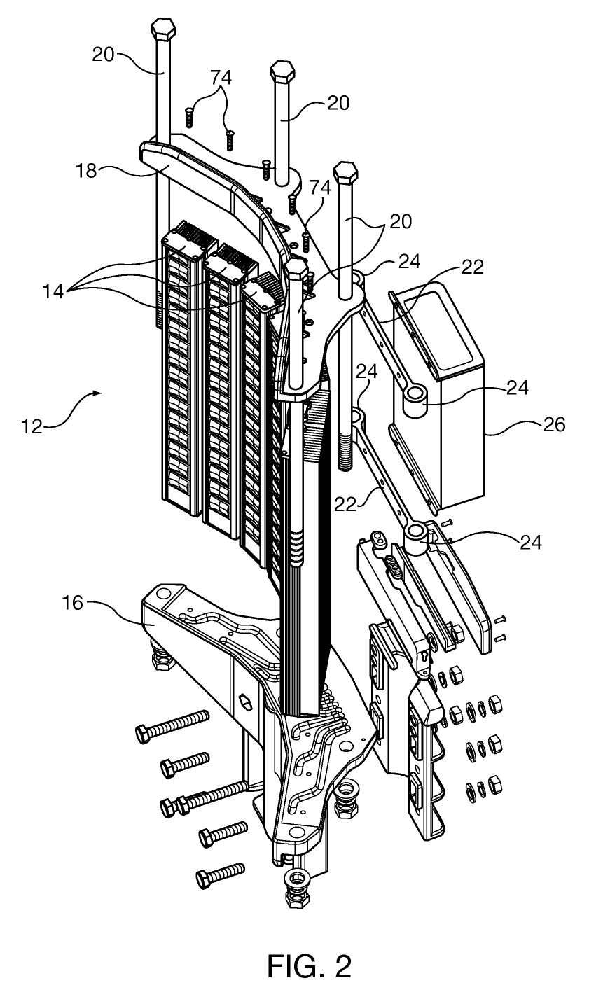

The modular luminaire 10 may be of a type in which a plurality of heat sinks 14 are suspended between a proximal end piece 16 and a distal end piece 18 of the modular luminaire 10. Individual component parts of the modular luminaire 10 are better seen in the exploded view of FIG. 2.

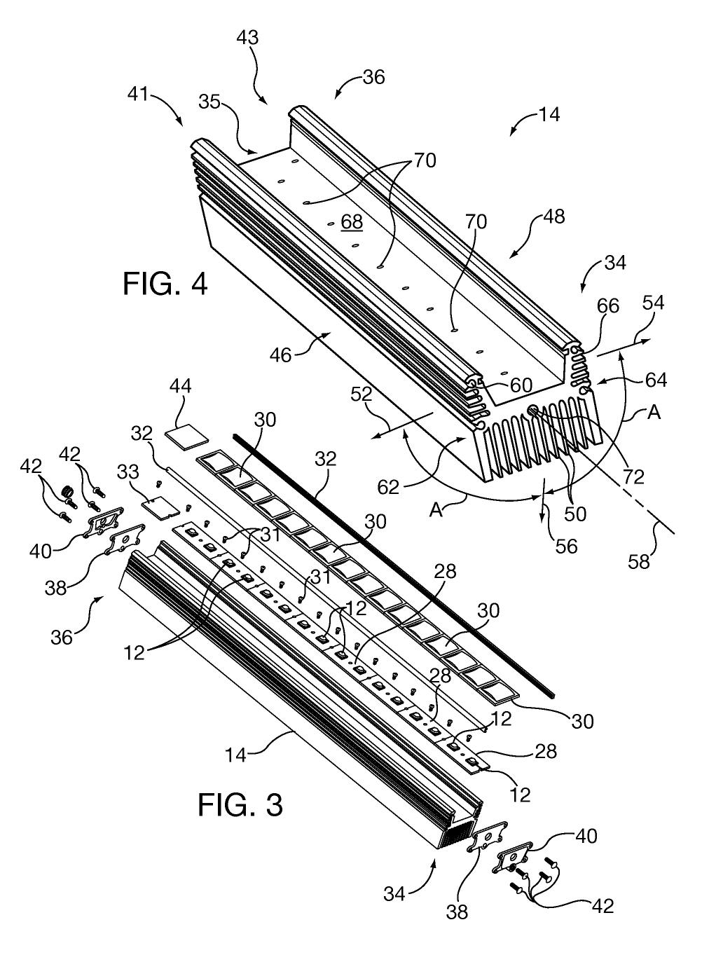

FIG. 3 shows components of an individual heat sink 14 and parts which are connected thereto to establish a usable modular bloc of LEDs 12. A plurality of LEDs 12 is mounted on printed circuit boards 28 (not all of which are individually called out by reference numeral) in conventional fashion. The printed circuit boards 28 may be mounted to the heat sink 14 as will be described hereinafter. A lens 30 (not all of which are individually called out by reference numeral) is provided to cover each LED 12.

Each heat sink 14 may be said to have a base or platform 35 (see FIG. 4), a proximal end 34, a distal end 36, and a length defined therebetween, although designation as proximal or distal in this case is only a semantic convenience. For example, the proximal end 34 may be that engaged and supported at a proximal end of the modular luminaire 10, while the distal end 36 may be that supported by the distal end of the modular luminaire 10.

The LEDs 12 are located between the proximal end 34 and the distal end 36, and may for example be ordered in straight rows. Of course, other arrays of LEDs 12 on each heat sink 14 are possible.

A heat sink 14 isolated from its associated components, such as the LEDs 12 and printed circuit boards 28 is shown in FIG. 4. The heat sink 14 is seen to have a base or platform 35, lateral cooling fins 46, 48 and top cooling fins 50.

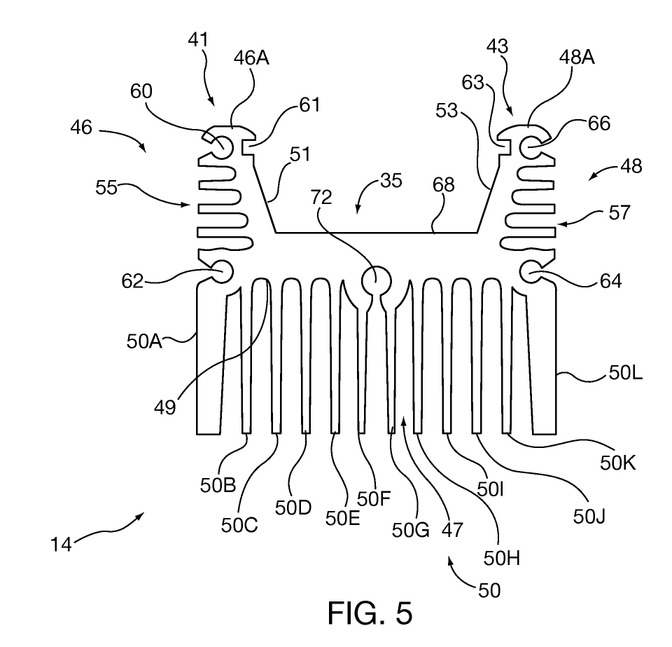

As best seen in FIG. 5, two short walls 41, 43 project upwardly along each side of an upwardly facing surface 68, which in FIG. 4 may be the upper surface of the body 35. The fins 46 may project from the wall 41 (see FIG. 4). The fins 48 may project from the wall 43. All of the fins 46, 48, 50 may be parallel to the central axis 58, seen in FIG. 4.

Again referring to FIG. 5, a gap is defined between every two adjacent fins 46, 48, 50. Illustratively, a gap 47 is formed between the fins 50G and 50H. Other gaps are also present, but are not called out by reference numeral. Each gap has a width, which refers to the distance between adjacent fins, such as the fins 50G, 50H.

Gaps are also present between adjacent cooling fins 46, such as the gap 55, and between adjacent cooling fins 46, such as the gap 57.

A floor surface is defined on the body 35 between any two fins, such as the floor surface 49 formed between the fins 50B, 50C. The floor surface may be the outer surface of the body 35 between two adjacent fins, such as the fins 50.

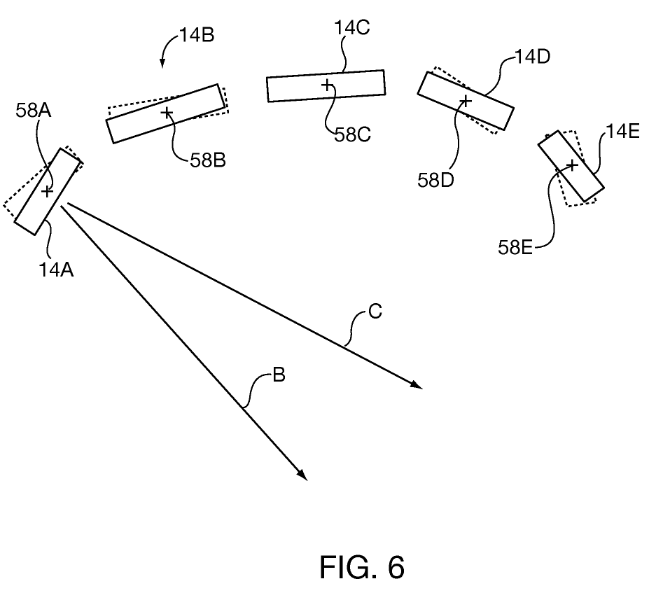

A fastener hole 72 may be formed at the central axis 58 of the heat sink 14, and more particularly, may overlie the central axis 58. The location of the fastener hole 72 enables angular adjustment of heat sinks 14 and hence of LEDs. This is described hereinafter with reference to FIG. 6.

Five fastener thread receiving channels 60, 62, 64, 66, 72 may be formed in the heat sink 14. Each one of the fastener thread receiving channels 60, 62, 64, 66, 72 may be formed at the floor surface of the body 35 or at the corresponding floor surfaces of the walls 41, 43 (see FIG. 4) between two of the fins 46, 48, or 50. The fastener thread receiving channels 60, 62, 64, 66, 72 are generally circular in cross sectional configuration when viewed from the end, as seen in FIG. 5, except where the fastener thread receiving channels 60, 62, 64, 66, 72 are open to the exterior of the heat sink 14. The diameter of each one of the fastener thread receiving channels 60, 62, 64, 66, 72 may be greater in magnitude than is the width of the gap associated with that fastener thread receiving channel 60, 62, 64, 66, or 72. The diameters are taken in a plane which is perpendicular to the central axis 58 of the heat sink.

FIG. 5 also shows that the wall 41 may have an inclined inner surface 51. Similarly, the wall 43 may have an inclined inner surface 53. When considered in end elevation, as seen in FIG. 5, the inclined inner surfaces 51, 53 define an acute angle therebetween. The inclined inner surfaces 51, 53 enable both a wider angle of light propagation from the LEDs 12 and also enable greater dissipation of heat from the LEDs 12 than would occur if the inner surfaces were perpendicular to the upwardly facing surface 68 (see FIG. 4).

It will be seen that the outermost fins 50A, 50L are thicker than the other cooling fins 50B, 50C, 50D, 50E, 50F, 50G, 50H, 501, 50J, and 50K.

The outermost cooling fins 46A, 48A of the respective walls 41, 43 are generally curved in cross section along their entire length when considered in end elevation.

Another feature of the heat sink 14 is grooves 61, 63 formed respectively in the walls 41, 43. These grooves may receive flanges formed in lenses, such as the lenses 30, to assist in securing the lenses in place on the heat sink 14.

The lateral cooling fins 46 may project in a direction represented by the arrow 52. The lateral cooling fins 48 may project in a direction represented by the arrow 54. The bottom cooling fins 50 may project in a direction represented by the arrow 56. The directions of the arrows 52, 54, 56 may be arranged such that each direction is perpendicular to an adjacent direction. Alternatively stated, a right angle A may exist between any two adjacent ones of the directions indicated by the arrows 52, 54, 56.

However, it is not necessary that perpendicularity be present. It is desired that the cooling fins 46, 48, 50 face in three substantially different directions outwardly away from the central axis 58.

As employed herein, orientational terms such as top and bottom will be understood to refer to the orientations depicted in the referenced drawing figures. Therefore, orientational terms must be understood to provide semantic basis for purposes of description, and do not limit the invention or its component parts in any particular way. This also holds true as to designation of the fins 50 as being at the bottom of their associated heat sink 14. The location of the fins 50 may change due because a modular luminaire such as the luminaire 10 may be mounted in any orientation.

It will be seen that all of the fins are longitudinally oriented in that they are parallel to the central longitudinal axis 58 of the heat sink 14. Also formed in the heat sink 14 may be a plurality of fastener thread receiving channels 60, 62, 64, 66, which extend along the length of their associated heat sink 14. Screws 42 (see FIG. 3) which may be self-tapping screws, or which may otherwise be sufficiently robust as to thread to the fastener thread receiving channels 60, 62, 64, 66 may be employed without the necessity of drilling and tapping screw holes. It will be appreciated that all of the features of the heat sink 14 which may be seen in end elevation, such as the fins 46, 48, 50 and also the fastener thread receiving channels 60, 62, 64, 66, may be advantageously and inexpensively formed for example by an extrusion process, although other fabrication methods such as casting or injection molding could be employed if desired.

It will also be seen in FIG. 6 that the overall perimetric boundary of the heat sink 14 may approximate the configuration of a rectangle. This may be achieved by coordinating the outermost extent of the fins 46, 48, and 50, and the uppermost surfaces of the walls 41 and 43.

It will also be seen that the thicknesses of the body 35 and of the walls 41 and 43 may be relatively constant along more than half of their respective widths. As depicted in FIG. 5, the widths of the walls 41 and 43 extend vertically, with the respective thicknesses being shown in a horizontal plane. Similarly, the width of the body 35 extends in a horizontal plane in FIG. 5, with the thickness being shown in a vertical plane.

FIG. 4 also shows a mounting surface 68 for mounting the printed circuit boards 28 and fastener holes 70 which may be drilled into the heat sink 14 after extrusion, for receiving fasteners to secure the printed circuit boards 28 to the heat sink 14.

Referring to FIG. 6, five representative heat sinks 14A, 14B, 14C, 14D, 14E are shown. These heat sinks 14A, 14B, 14C, 14D, 14E may be structural and functional counterparts to the heat sinks 14 described priorly, for example. The heat sinks 14A, 14B, 14C, 14D, 14E are angularly adjustable about their respective central longitudinal axes 58A, 58B, 58C, 58D, 58E. Representative angular adjustment of the heat sinks 14A, 14B, 14D, 14E is depicted, showing one position in solid lines and an alternative position in broken lines. Considering the heat sink 14A as an example, the directions of the center line of light propagation is indicated by the arrows B and C. The center heat sink 14C could be angularly adjusted if the resulting asymmetry of light projection were deemed not objectionable.

It is an important characteristic of the heat sink 14 that the body 35, the first wall 41, the second wall 43, and the fastener thread receiving channels 60, 62, 64, 66, and 72 individually and collectively display invariable cross section continuously along the entire length of the heat sink 14. This characteristic enables heat sinks 14 to be extruded to any desired length, or to be cut to any desired length, without losing structure for receiving fasteners which are may be driven into the fastener thread receiving channels 60, 62, 64, 66, and 72. This greatly enhances modularity of the heat sink 14 as well as versatility in accommodating luminaires of different dimensions and capacities.

The present invention is susceptible to modifications and variations which may be introduced thereto without departing from the inventive concepts. For example, although the invention has been described with respect to individual LEDs, it would be possible to provide LEDs in pluralities or clusters (not shown), with each cluster being treated as described priorly with regard to individual LEDs. The flat mounting surface 68 easily accommodates different LED arrays. Also, LEDs need not be arrayed in perfect linear rows as illustrated, provided that a plurality of LEDs is provided along the length of each heat sink, such as the heat sink 14.

While the present invention has been described in connection with what is considered the most practical and preferred embodiment, it is to be understood that the present invention is not to be limited to the disclosed arrangements, but is intended to cover various arrangements which are included within the spirit and scope of the broadest possible interpretation of the appended claims so as to encompass all modifications and equivalent arrangements which are possible.

I claim:

1. A heat sink for supporting and dissipating heat from LEDs used in a luminaire comprising:
a body having a proximal end, a distal end, length defined between the proximal end and the distal end, and a central axis which extends along said length, and an upwardly facing surface;
a first wall projecting upwardly along one side of said upwardly facing surface of said flat base;
a second wall projecting upwardly from an opposed side of said upwardly facing surface of said flat base;
a plurality of fins projecting from said body, which said fins are parallel to said central axis, wherein between any two of said fins, a floor surface is defined on said body; and
at least one fastener thread receiving channel which is formed at the floor surface between two of said fins, wherein
a gap having a width is defined between every two adjacent said fins, and said fastener thread receiving channel has a diameter taken perpendicularly to said central axis of magnitude greater than the magnitude of an associated said gap.

2. The heat sink of claim 1, wherein said body, said first wall, said second wall, said fins, and said fastener thread receiving channel collectively display invariable cross section continuously along the entire length of said heat sink.

3. The heat sink of claim 1, wherein each said fastener thread receiving channel is circular in cross section along its entire length except where said fastener thread receiving channel is open to its associated said gap.

4. The heat sink of claim 1, wherein said first wall comprises a plurality of longitudinally oriented cooling fins extending from said first wall in a direction away from said central axis, and said second wall comprises a plurality of longitudinally oriented cooling fins extending from said first wall in a direction away from said central axis.

5. The heat sink of claim 1, wherein there are a plurality of said fastener thread receiving channels formed therein and extending along the length of said heat sink, and wherein one of said fastener thread receiving channels overlies said central axis of said heat sink.

6. The heat sink of claim 1, wherein said cooling fins of said body face in a direction away from said upwardly facing surface, said cooling fins of said first wall face in a substantially different direction, and said cooling fins of said second wall face in a direction which is substantially different from those of said cooling fins of said body and said cooling fins of said first wall.

7. The heat sink of claim 1, wherein said first wall has an inclined inner surface, said second wall has an inclined inner surface, and wherein when considered in end elevation said inclined inner surface of said first wall and said inclined inner surface of said second wall define an acute angle therebetween.

8. The heat sink of claim 1, wherein the outer configuration of said heat sink, when considered in end elevation, is formed by an extrusion process. heat sink is extruded

9. The heat sink of claim 1, wherein the outermost said cooling fins of said body are thicker than the other said cooling fins of said body.

10. The heat sink of claim 1, wherein the outermost said cooling fins of said first wall and the outermost said cooling fins of said second wall are curved in cross section along their entire length when considered in end elevation.
